(19) United States
(12) Patent Application Publication
(10) Pub. No.: US 2009/0206450 A1
(43) Pub. Date: Aug. 20, 2009

(54) METHOD OF MANUFACTURING A SEMICONDUCTOR DEVICE, SEMICONDUCTOR DEVICE OBTAINED HEREWITH, AND SLURRY SUITABLE FOR USE IN SUCH A METHOD

(75) Inventor: Srdjan Kordic, Biviers (FR)

Correspondence Address: NXP, B.V.;NXP INTELLECTUAL PROPERTY & LICENSING, M/S41-SJ, 1109 MCKAY DRIVE, SAN JOSE, CA, 95131, US

(73) Assignee: NXP B.V., Eindhoven (NL)

(21) Appl. No.: 12/298,278

(22) PCT Filed: Apr. 24, 2007
(86) PCT No.: PCT/IB07/51491

§ 371 Date: Oct. 23, 2008

(30) Foreign Application Priority Data
Apr. 26, 2006 (EP) 06300405.5

(51) Int. Cl. H01L 21/306; H01L 21/66; C09K 13/00; H01L 29/00; B24B 1/00; B24B 49/12

(52) U.S. Cl. 257/618; 438/692; 438/8; 252/79.1; 257/E21.23; 257/E21.528; 257/E29.001; 451/36; 451/6

(57) ABSTRACT

The invention relates to a method of manufacturing a semiconductor device (10) with a substrate (11) and a semiconductor body (2) which is provided with at least one semiconductor element and the surface of which is provided with an aluminum layer (3) that is patterned by means of a chemical-mechanical polishing process, the side of the device (10) covered with the aluminum layer (3) being pressed against a polishing pad (5), the device (10) and the pad (5) being moved with respect to each other, a slurry (6) containing an abrasive and having a pH level lower than about 12 being applied between the device (10) and the pad (5), and the polishing process being continued till a sufficient amount of the aluminum layer (3) has been removed. According to the invention, the slurry (6) between the device (10) and the pad (5) is provided with a pH level lower than 5 and the pH level is created using merely an acid the aluminum salt of which dissolves well in the slurry (6). In this way, a device (10) is obtained in a reproducible manner, having an aluminum pattern (3) with a reflective and defect-free surface. Good results have been obtained with a slurry (6) containing lactic acid.

The invention relates to a method of manufacturing a semiconductor device with a substrate and a semiconductor body which is provided with at least one semiconductor element and the surface of which is covered with an aluminum layer which is patterned by means of a chemical mechanical polishing process, wherein the semiconductor device is pressed with its side covered with the aluminum layer against a polishing cloth, and the semiconductor device and the polishing cloth are moved with respect to each other, an abrasive-containing slurry provided with a pH level lower than 12 being provided between the polishing cloth, a so-called pad, and the semiconductor device, and the polishing process continuing until a sufficient amount of the aluminum layer has been removed.

Such a method is especially suitable for the manufacturing of Integrated Circuits (ICs). When using a 32 nm technology, about 10% of the series resistance will be caused by CVD (Chemical Vapor Deposition)-deposited tungsten at contact level. This is caused by the relatively high resistivity of tungsten. When a 22 nm technology is used, a reduction of more than 20% of the series resistance can be obtained by using materials such as copper or aluminum. Attempts in several technologies to use copper at contact level instead of tungsten are only partly successful, because the contacts have to be provided with high aspect ratios by means of a PVD (Physical Vapor Deposition)-deposited copper nucleation layer and an ECD (Electro Chemical Deposition)-deposited copper layer. This is caused by the fact that a CVD-deposited layer is not available. Therefore, the combination of a CVD TiN barrier layer and a CVD aluminum layer constitutes an attractive alternative in combination with these technologies, also due to the low contact resistance. An aluminum pattern can also function as a wiring pattern. The use of a CMP (Chemical Mechanical Planarization or Chemical Mechanical Polishing) process to pattern an aluminum layer which has been applied in damascene technology, is particularly suitable in this case.

Such a method is known from American patent U.S. Pat. No. 6,720,265, which describes how an aluminum layer is planarized at contact level of an IC by means of CMP. The device is held with its aluminum layer against a pad, while at the interface between aluminum layer and pad a slurry is added which contains an abrasive in the form of SiO2 particles and is preferably composed of a surface active substance, a complexing substance and an oxidant, and the solution has a pH level lower than approximately 12. The pad as well as the device rotate with respect to non-concentric rotation axes. The force with which the device presses against the pad can be adjusted and the slurry is supplied here through openings in the rim of a holder of the device and the openings are concentrically grouped with respect thereto.

A drawback of the known method is that it does not always produce a reflective aluminum surface after the CMP process. Damage of the aluminum layer occurs which leads to (surface) defects and/or corrosion. Another drawback of the known method is that the speed at which the aluminum layer is removed in the CMP process does not always reproduce well.

The object of the invention is therefore to provide a method which does not show the drawbacks mentioned, or at least to a lesser extent, and which produces ICs with an aluminum contact layer patterned by means of CMP, which is reflective, free of defects and has a reproducible removal speed.

To this end, a method of the kind mentioned in the opening paragraph is characterized according to the invention in that the slurry has a pH level lower than 5 and the pH level is obtained by exclusively using an acid the aluminum salt of which dissolves well in the slurry. Surprisingly, it has turned out on the one hand that, with this combination of measures, the surface of a CMP-treated aluminum contact layer reflects very well, is without defects and also reproduces particularly well the speed at which the aluminum layer is removed during the CMP process. An important insight here is that during a CMP process, which, for setting the pH level, uses an obvious acid for a CMP process of aluminum, aluminum salts develop which are not, or hardly, soluble. The presence of these insoluble products can, on the one hand, lead to damage of the aluminum layer's surface and, on the other, these products accumulate in the (hairy) surface of the polishing pad. This causes the effectiveness of the polishing pad to diminish rather rapidly and the removal speed of the aluminum layer during the CMP process to decrease. It is true that a rise in temperature of the slurry during the CMP process could improve this, but such a rise in temperature is undesirable for a CMP process. The (rough) cleaning of the surface of the polishing pad could also be considered to achieve said improvement, but this causes the method to become time-consuming and expensive due to an increased use of polishing pads.

In a preferred embodiment, the pH level of the slurry is set to between 2 and 4. Good results have been obtained with such a slurry for planarising ICs. The pH level of the slurry is set preferably to between 2 and 3. The reproducibility in particular benefits from such a choice of pH level.

The acid, by means of which the pH level is set, is preferably lactic acid. The solubility of aluminum salts in an (aqueous) slurry for use in a method according to the invention is excellent and the experimental results with regard to the quality of a planarised aluminum surface and reproducibility of the removal speed of aluminum are accordingly.

In a favorable embodiment, no oxidizing agent is added to the slurry, at least not on purpose. Surprisingly, it has been found that, by using a method according to the invention, the above-discussed favorable results are possible without adding an oxidizing agent to the slurry. This means that no such oxidizing agent has to be added to the slurry, at least not on purpose. This causes a method according to the invention to be relatively cheap and the slurry (used) to have little environmental impact. Not on purpose means that there may be, for example, an oxidizing agent such as oxygen in the slurry because, when the slurry is exposed to air, depending on the temperature and motion of the slurry, there will always be a certain amount of oxygen that dissolves in it.

Another interesting embodiment is characterized in that the slurry is formed by providing a slurry having a pH level of about 10 and being suitable for the chemical mechanical polishing of a silicon oxide, with an amount of acid such that the required pH level is obtained. Partly because in a method according to the invention no oxidant has to be added on purpose, a slurry suitable for CMP of a silicon oxide—which, as mentioned above, does not contain an oxidant—can be applied to advantage. The excess lye is titrated away by adding the (lactic) acid, and the resulting salt—which also dissolves easily in the slurry—has relatively little environmental impact. As for CMP of silicon oxide as well as for CMP of aluminum, one and the same initial solution can be used, the efficiency of the IC production is improved.

Experiments have shown that the best results are obtained when, in a method according to the invention, a non-fresh solution of a slurry suitable for CMP of a silicon oxide is used. Preferably, the pH level of the slurry suitable for the chemical-mechanical polishing of a silicon oxide, which pH is about 10, is reduced to approximately 9, and after a waiting period the pH level is further reduced. Reducing the pH level to 9 can be done by means of lactic acid but also by blowing carbon dioxide through the slurry. A subsequent waiting period of about 24 hours is suitable in those cases. Subsequently, the pH level of the slurry can be reduced even further, for example to a pH level of about 2, after which a slurry thus prepared is ready for use. The useful life of the slurry eventually obtained is about one week. After that time it decreases as jellification of the slurry takes place.

The slurry can be inserted in various ways at the relevant place between the semiconductor device and the polishing pad. This can be done according to the known method but also by dripping the slurry on the polishing pad in a single spot slightly more remote from the semiconductor device. Mutual movements of device and pad then cause the slurry to be transported to the desired position. The polishing process may be accompanied by movement of the device or the pad or—preferably—both. Device and pad can, for example, rotate about an axis, during which process the rotation axes do not coincide. A so-called orbital rotation of one of them can also be applied to advantage.

In an important embodiment, the end point of the chemical-mechanical polishing process is optically detected. On the one hand, this is a very reliable way of detection, on the other, a ‘disadvantage’ of the method according to the invention, i.e. that it has no or relatively little selectivity in the case of CMP of an aluminum layer as well as a silicon (di)oxide containing layer, is overcome. Moreover, the ‘disadvantage’ of little selectivity is actually an advantage, as the surface of a semiconductor device which in practice contains an aluminum layer as well as a silicon dioxide layer, is not or hardly profiled when using a method according to the invention.

The invention also comprises a semiconductor device obtained by using a method according to the invention. The invention furthermore comprises a chemical-mechanical polishing slurry suitable for use in a method according to the invention, which is characterized in that the slurry contains an abrasive, has a pH level lower than 5 and exclusively contains an acid the aluminum salt of which dissolves easily in the slurry. When preparing such a slurry, use can advantageously be made of a starting slurry suitable for a CMP process of a silicon (di)oxide layer. A waiting period during the preparation process is necessary to obtain the desired result.

These and other aspects of the invention are apparent from and will be elucidated with reference to the embodiment(s) described hereafter:

In the drawings:

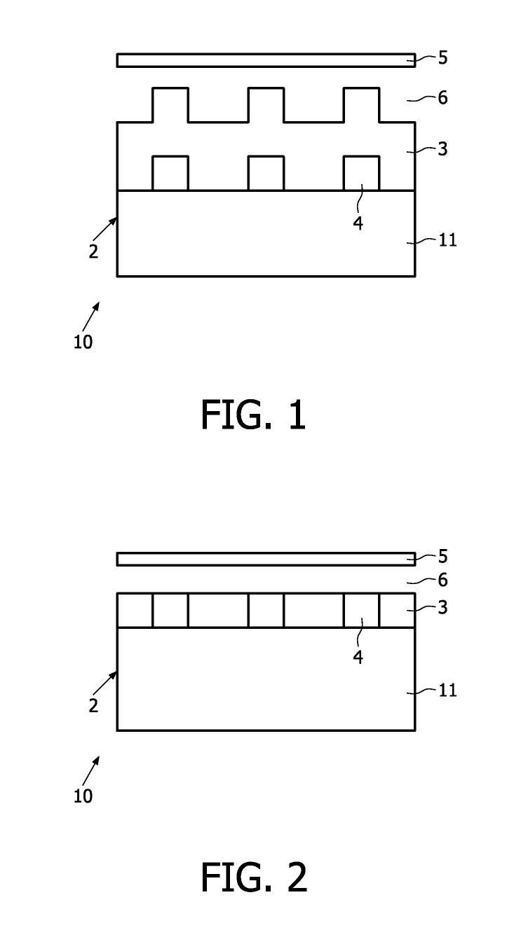

FIGS. 1 and 2 are diagrammatic cross-sectional views, at right angles to the thickness direction, of a semiconductor device in successive stages of the manufacturing process, using a method in accordance with the invention,

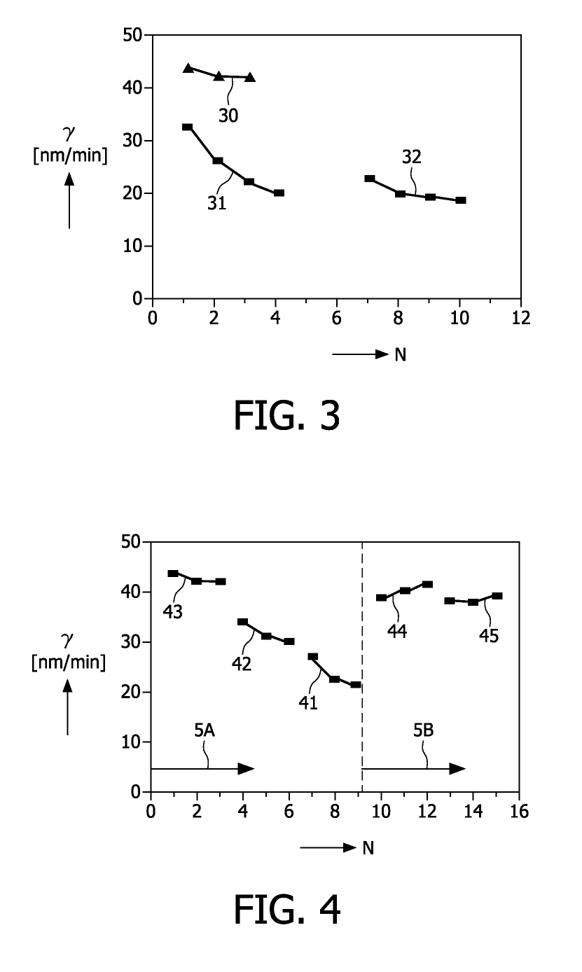

FIG. 3 shows the speed at which an aluminum layer is removed as a function of the number of devices treated in a method in accordance with the invention and in a known method,

FIG. 4 shows the speed at which an aluminum layer is removed as a function of the number of devices treated in a method according to the invention for different pH levels of the slurry used, and

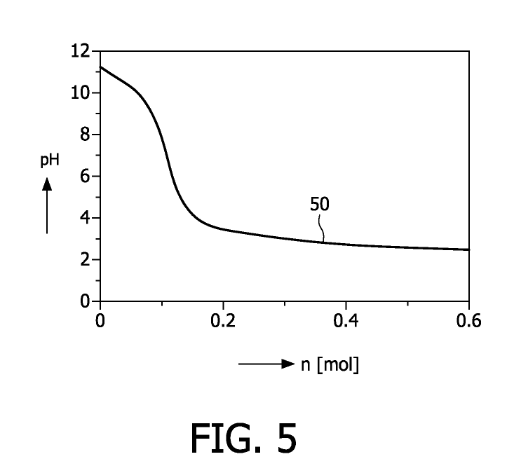

FIG. 5 shows the pH level of a slurry suitable for use in a method according to the invention, as a function of the quantity of acid added.

The Figures are not drawn to scale and some dimensions are exaggerated for the sake of clarity. Corresponding areas or parts have been given the same hatching and the same reference numbers as much as possible.

FIGS. 1 and 2 are diagrammatic cross-sectional views, at right angels to the thickness direction, of a semiconductor device in successive stages of the manufacturing process using a method in accordance with the invention. In this case, a device 10 comprises (see FIG. 1) a substrate 11 which is part of a silicon semiconductor body 2 in which, in this case, a large number of semiconductor elements have been created in the form of an IC. On the surface of the semiconductor body 2 an insulating layer 4 is applied in this case, for example through CVD, and this layer is patterned by means of photolithography and etching. An aluminum layer 3 is superposed on this, for example through evaporation or CVD; in this example, the surface of layer 3 as well as the surface of silicon dioxide layer 4 provided with apertures is profiled.

The device 10 is accommodated in a holder—not shown in the drawing—and a polishing pad 5 is positioned opposite the device 10. Unlike the drawing, in this example the holder with the device 10 is located above the pad 5, which furthermore also partly extends sideways beyond device 10. On the pad 5 a slurry 6 is provided drop-wise. As the rotating movements of device 10 and pad 5 do not coincide, the slurry 6 is transported to between device 10 and pad 5. Thus, the device 10 is situated in a chemical-mechanical polishing machine such as MIRRA or REFLEXION from Applied Materials. The force exercised on pad 5 and device 10 can be adjusted.

The slurry 6 in this example is based on a slurry suitable for the chemical-mechanical polishing of a layer containing silicon (di)oxide. Such a slurry contains an abrasive, for example, in the form of cured (?) silicon dioxide particles and has a pH level of 10 to 11 due to the addition of a base such as KOH. For such a slurry, a slurry from Syton or an (IC grade) slurry from Cabot, for example SS12/SSW12, can be used, if required diluted with demi water. By adding lactic acid to this slurry or passing carbon dioxide through it, the pH of the slurry is reduced to a level of about 9. This slurry 6 is subsequently stored for about 24 hours. Then, lactic acid (hydroxypropion acid=CH₃C(OH)CO₂H) is (again) added to the slurry 6 until it has reached a pH level lower than 5. In this example, the pH level is set to about 2.5. The slurry 6 thus obtained, which can be kept for about a week, is then inserted between the device 10 and the pad 5, as described above.

Subsequently, (see FIG. 2) a chemical-mechanical polishing process is carried out during which part of the aluminum layer 3 is removed. This process is continued until the top of the insulating pattern 4 is free of aluminum; an optical detection method is an excellent way to determine this. In this way, a damascene process forms an aluminum 3 pattern within the silicon dioxide pattern, the surface of the aluminum 3 being reflective, fault free and coplanar with the upper surface of the silicon dioxide 4.

The effectiveness and reproducibility of the method according to the invention compared to, for example, a method using a slurry which has been acidified with phosphoric acid is illustrated with reference to FIG. 3.

FIG. 3 shows the removal speed (r) of an aluminum layer as a function of the number of devices (N) treated in a method according to the invention and a prior-art method. It is noted that the number N represents in fact the number of semiconductor slices treated. Every semiconductor slice contains a larger number of semiconductor devices, such as ICs, which in turn will each contain a large number of semiconductor elements, such as transistors. Usually, the ICs within a slice are treated simultaneously. Curve 30 shows the results of the method according to the invention as described above. Curves 31 and 32 show the results of a method in which the slurry is acidified with phosphoric acid, and they apply, respectively, to experiments in which the polishing pad 5 has and has not been brushed. When comparing the results, it becomes clear that a method according to the invention not only results in a high removal speed of the aluminum, but also a removal speed which provides excellent reproducibility. This is in contrast with methods which use phosphoric acid and in which the speed at which aluminum is removed is lower and reproduction is less good. Inspection of the aluminum layer's surface also shows that, contrary to the known method, the aluminum surface treated according to a method of the invention is reflective and fault free. Similar, good results have also been obtained for a number of slices N varying from 15 to 20.

The influence of the pH level of the slurry in a method according to the invention can be illustrated as follows.

FIG. 4 shows the removal speed (r) of an aluminum layer as a function of the number of devices (N) treated in a method according to the invention for various pH levels of the slurry used. Curves 41, 42 and 43 show the results for a pH level of 4.5, 3.5 and 2.5, respectively, using a first polishing pad 5A. Curves 44 and 45 show the results for a pH level of the slurry of 2.4 and 1.9, respectively, using a second polishing pad 5B. These results indicate that reproducibility is at its best at the lower pH levels, as shown by curves 43, 44 and 45, which have a pH level in the range of 2 to 3.

Finally, FIG. 5 shows the pH level of a slurry suitable for use in a method according to the invention as a function of the amount of acid added. The starting material is an alkaline slurry, such as a slurry from Syton or Cabot, which is suitable for CMP of a silicon oxide layer and which is provided with a low pH level by means of lactic acid. Curve 50 shows the pH level of such a slurry as a function of the number of lactic acid moles added (n). As curve 50 shows, the variation of the pH level in the 2 to 5 range has a relatively flat profile. This means that, in that range, the pH level can be set fairly accurately.

Reference numbers in the claims do not limit the scope of protection thereof. The invention is not limited to the examples presented, as for the person skilled in the art there are—within the scope of the invention—many possibilities for variation and modification. The invention can, for example, be applied not only to ICs but also to discrete semiconductor devices.

Many variations and modifications are also possible for a method according to the invention. For instance, other deposition techniques can be used and other materials than the ones in the example can be chosen. Also, the aluminum layers do not necessarily have to consist of completely pure aluminum and other elements may be added to improve the (electrical) properties.

It is furthermore noted that it is also possible to obtain a suitable slurry and method by applying dilution in water. It is true that the speed of removal of the aluminum will decrease somewhat, but the costs of the slurry can be significantly lower.

Finally, it is noted that the polishing pad can also be cleaned with a lactic acid solution, and that this can be done at times when the pad is not in use, such as during the transport of semiconductor slices in the CMP equipment.

1. Method of manufacturing a semiconductor device with a substrate and a semiconductor body which is provided with at least one semiconductor element and the surface of which is covered with an aluminum layer which is patterned by means of a chemical-mechanical polishing process, wherein the semiconductor device is pressed with its side covered with the aluminum layer against a polishing pad, and the semiconductor device and the polishing pad are moved with respect to each other, an abrasive-containing slurry provided with a pH level lower than 12 being provided between the polishing pad and the semiconductor device and the polishing process continuing until a sufficient amount of the aluminum layer has been removed, characterized in that the slurry has a pH level lower than 5 which is obtained by only using an acid the aluminum salt of which easily dissolves in the slurry.

2. Method as claimed in claim 1, characterized in that the pH level of the slurry is set between 2 and 4.

3. Method as claimed in claim 1, characterized in that the pH level of the slurry is set between 2 and 3.

4. Method as claimed in claim 1, characterized in that the acid used for setting the pH level of the slurry is lactic acid.

5. Method as claimed in claim 1, characterized in that no oxidant is added to the slurry, at least not on purpose.

6. Method as claimed in claim 1, characterized in that the slurry is formed by providing a slurry having a pH level of about 10 and being suitable for the chemical-mechanical polishing of a silicon oxide with an amount of acid such that the required pH level is obtained.

7. Method as claimed in claim 6, characterized in that the slurry which is suitable for CMP of a silicon oxide and which has a pH level of about 10, is first provided with a pH level of about 9 and, after a waiting period, with a lower pH level.

8. Method as claimed in claim 1, characterized in that the slurry is applied next to the semiconductor device on the polishing pad.

9. Method as claimed in claim 1, characterized in that the end point of the chemical-mechanical polishing process is optically detected.

10. Semiconductor device obtained by means of a method as claimed in claim 1.

11. Chemical-mechanical polishing slurry suitable for use in a method as claimed in claim 1, characterized in that the slurry contains an abrasive, has a pH level lower than 5 and only contains an acid the aluminum salt of which easily dissolves in the slurry.
